(19) United States
(12) Patent Application Publication
(10) Pub. No.: US 2011/0012184 A1
(43) Pub. Date: Jan. 20, 2011

(54) SEMICONDUCTOR MEMORY DEVICE

(75) Inventor: Kazuyoshi YUKI, Tokyo (JP)

Correspondence Address: YOUNG & THOMPSON, 209 Madison Street, Suite 500, Alexandria, VA, 22314, US

(73) Assignee: ELPIDA MEMORY, INC., Tokyo (JP)

(21) Appl. No.: 12/829,683

(22) Filed: Jul. 2, 2010

(30) Foreign Application Priority Data
Jul. 17, 2009 (JP) 2009-168923

(51) Int. Cl. H01L 27/108

(52) U.S. Cl. 257/306; 257/E27.084

(57) ABSTRACT

A semiconductor memory device including: word lines extending in a Y direction on a semiconductor substrate, the word lines being arranged in an X direction perpendicular to the Y direction and being parallel to one another; active regions each elongating and intersecting with two of the word lines, the active regions being arranged in the Y direction and being parallel to one another on the semiconductor substrate; a capacitance contact plug connected to each end of each of the active regions in the longitudinal direction thereof; a stack lower electrode including a first lower electrode formed on the capacitance contact plug and a second lower electrode formed on the first lower electrode; a capacitance insulating film; and an upper electrode, wherein the center position of the second lower electrode is shifted in a predetermined direction from the center position of the first lower electrode.

### BACKGROUND OF THE INVENTION

1. Field of the Invention

The present invention relates to a semiconductor memory device.

2. Description of Related Art

Along with an advance in the miniaturization of semiconductor devices, the area of a memory cell constituting a DRAM (Dynamic Random Access Memory) has also diminished. Accordingly, it is practiced to form a capacitor constituting the memory cell into a three-dimensional shape, in order to ensure sufficient electrostatic capacitance for the capacitor. Specifically, the lower electrode of the capacitor is processed into a cylindrical shape (cylindrical capacitor) or a pillar shape (columnar capacitor) and the capacitor is formed by utilizing the sidewalls thereof, thereby increasing the surface area of the electrode.

Due to a reduction in the area of the memory cell, however, the bottom area of the capacitor lower electrode has also diminished. Accordingly, a hole having a high aspect ratio needs to be formed in an interlayer insulating film, in order to form such a cylindrical or pillar capacitor. With an increase in the aspect ratio, however, it becomes more difficult to form a hole having a desired shape by dry etching.

JP2004-311918A describes a technique which uses a capacitor lower electrode including a pad-shaped (box-shaped or non-hollow cylinder-shaped) storage node and a cap-shaped storage node disposed on this storage node, in order to solve problems caused when the height of a storage node (capacitor lower electrode) increases.

On the other hand, JP2007-287794A describes a technique to dispose memory cells into a 6 F² layout in a DRAM. In this technique, the center position of a storage node contact (capacitance contact plug) connected onto a cell contact (contact plug) is displaced from the center position of the cell contact. In addition, the center position of a storage node contact pad provided between this storage node contact and a capacitor is displaced from the center position of the storage node contact. The patent document describes that this technique enables a most densely packed arrangement of capacitors and an increase in electrostatic capacitance.

### SUMMARY

The technique described in JP2004-311918A is concerned with the structure of a capacitor lower electrode within each memory cell and is not intended to achieve high integration from the viewpoint of a layout of a plurality of memory cells.

Although the technique described in JP2007-287794A achieves high integration from the viewpoint of a layout of a plurality of memory cells, the storage node contact pad is provided between the capacitor lower electrode and the storage node contact (capacitance contact plug). Consequently, this technique requires steps of forming and patterning a conductive film used to form this pad. Thus, the technique has the problem of an increase in manufacturing costs.

In one exemplary embodiment, there is provided a semiconductor memory device including:

a semiconductor substrate;

a plurality of word lines extending in a Y direction on the semiconductor substrate, the word lines being arranged in an X direction perpendicular to the Y direction and being parallel to one another;

a plurality of active regions each elongating and intersecting with two of the word lines, the active regions being arranged in the Y direction and being parallel to one another on the semiconductor substrate;

a capacitance contact plug connected to each end of each of the active regions in the longitudinal direction thereof;

a stack lower electrode including a first lower electrode formed on the capacitance contact plug and a second lower electrode formed on the first lower electrode;

a capacitance insulating film formed on the stack lower electrode; and

an upper electrode formed on the stack lower electrode with an intervention of the capacitance insulating film,

wherein the center position of the second lower electrode is shifted in a predetermined direction from the center position of the first lower electrode.

In another exemplary embodiment, there is provided a semiconductor memory device including:

a memory cell region provided on a semiconductor substrate;

active regions;

word lines intersecting with the active regions, the active regions and the word lines being arranged in the memory cell region according to a 6 F² cell layout; and

a capacitor including a lower electrode, the capacitor being connected to a predetermined position of each of the active regions with an intervention of a capacitance contact plug;

wherein the lower electrode of the capacitor includes a first lower electrode directly connected to the capacitance contact plug and a second lower electrode directly connected to the first lower electrode; and

the center position of the second lower electrode is shifted in a predetermined direction from the center position of the first lower electrode.

According to an embodiment, it is possible to provide a highly-integrated semiconductor memory device including a capacitor having large electrostatic capacitance and capable of being manufactured at low costs.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a plan view illustrating the structure of a DRAM memory cell part of a semiconductor memory device in accordance with a first exemplary embodiment;

FIG. 2 is a cross-sectional view taken along the line A-A′ of FIG. 1;

FIG. 3 is a cross-sectional view for explaining a method for manufacturing the structure illustrated in FIGS. 1 and 2;

FIG. 4 is a cross-sectional view illustrating a structure after a step following a step of forming the structure illustrated in FIG. 3;

FIG. 5 is a cross-sectional view illustrating a structure after a step following a step of forming the structure illustrated in FIG. 4;

FIG. 6 is a cross-sectional view illustrating a structure after a step following a step of forming the structure illustrated in FIG. 5;

FIG. 7 is a cross-sectional view illustrating a structure after a step following a step of forming the structure illustrated in FIG. 6;

FIG. 8 is a cross-sectional view illustrating a structure after a step following a step of forming the structure illustrated in FIG. 7;

FIG. 9 is a cross-sectional view illustrating a structure after a step following a step of forming the structure illustrated in FIG. 8;

FIG. 10 is a cross-sectional view illustrating a structure after a step following a step of forming the structure illustrated in FIG. 9;

FIG. 11 is a cross-sectional view illustrating a structure after a step following a step of forming the structure illustrated in FIG. 10;

FIG. 12 is a plan view illustrating a layout of the DRAM memory cell part of the semiconductor memory device in accordance with the first exemplary embodiment;

FIG. 13 is a plan view for further explaining the layout illustrated in FIG. 12;

FIG. 14 is a plan view illustrating a modified example of the layout illustrated in FIG. 12;

FIG. 15 is a schematic view for explaining an arrangement of the lower-layer parts of capacitor lower electrodes with respect to the capacitance contact plugs in the layout illustrated in FIG. 12;

FIG. 16 is a schematic view for explaining an arrangement of the upper-layer parts of capacitor lower electrodes with respect to the lower-layer parts thereof in the layout illustrated in FIG. 12;

FIG. 17 is a cross-sectional view illustrating an in-process structure of each DRAM memory cell part in accordance with a second exemplary embodiment;

FIG. 18 is a plan view illustrating a layout of DRAM memory cell parts in accordance with the second exemplary embodiment;

FIG. 19 is a cross-sectional view illustrating a structure after a step following a step of forming the structure illustrated in FIG. 17; and

FIG. 20 is a cross-sectional view illustrating an in-process structure of a DRAM memory cell part in accordance with a third exemplary embodiment.

### DETAILED DESCRIPTION OF PREFERRED EMBODIMENTS

A semiconductor memory device according to one exemplary embodiment includes: a semiconductor substrate; word lines extending in a Y direction on the semiconductor substrate, the word lines being arranged in an X direction perpendicular to the Y direction and being parallel to one another; active regions each elongating in a belt-like manner and intersecting with two of the word lines, the active regions being arranged in the Y direction and being parallel to one another on the semiconductor substrate; capacitance contact plugs respectively connected to one and the other ends of each of the active regions in the longitudinal direction thereof; a stack lower electrode including a first lower electrode formed on each of the capacitance contact plugs and a second lower electrode formed on the first lower electrode; a capacitance insulating film formed on the stack lower electrode; and an upper electrode formed on the stack lower electrode with an intervention of the capacitance insulating film. The center position of the second lower electrode is shifted in a predetermined direction from the center position of the first lower electrode.

In the above-described semiconductor memory device, the arrangement of the first and second lower electrodes with respect to each active region includes one of a first layout in which the center position of the second lower electrode is shifted from the center position of the first lower electrode in such a direction as to come closer to the central part of the active region and a second layout in which the center position of the second lower electrode is shifted from the center position of the first lower electrode in such a direction as to move away from the central part of the active region. The first and second layouts can be arranged so as to be alternately applied with respect to the active regions in the Y direction.

In the above-described semiconductor memory device, the active regions can be arranged such that the longitudinal directions thereof extend along straight lines forming a predetermined angle with the X direction. In addition, the active regions can be laid out on the respective straight lines forming the predetermined angle with the X direction. Furthermore, the first and second layouts can be arranged so as to be alternately applied with respect to the active regions on the respective straight lines. The straight lines preferably form an angle of approximately 18° with the X direction.

In the above-described semiconductor memory device, bit lines intersecting with the word lines can be provided. The bit lines each can be connected to the central parts of the active regions in the longitudinal directions thereof, with an intervention of respective bit line contact plugs. The bit lines can be provided in a meandering manner along the X direction such that the bit lines include portions intersecting with the active regions and portions parallel to the longitudinal directions thereof.

In the above-described semiconductor memory device, the locations of the capacitance contact plugs and the first lower electrodes with respect to the respective active regions can be arranged such that the center positions of the first lower electrodes are shifted in such a direction as to come closer to the central parts of the active regions from the center positions of the capacitance contact plugs. At that time, the center positions of the first lower electrodes are preferably shifted along the X direction.

In the above-described semiconductor memory device, the offset of the center positions of the second lower electrodes is preferably ¾ F along the X direction and ⅓ F along the Y direction. In addition, a distance between the centers of the second lower electrodes adjacent to each other along the X direction is preferably 3 F. Furthermore, a distance along the Y direction between the centers of the second lower electrodes adjacent to each other in the Y direction and displaced in the X direction is preferably 2 F.

In the above-described semiconductor memory device, the plurality of active regions can include first, second and third active regions continuously laid out along the Y direction in the named order, and fourth, fifth and sixth active regions continuously laid out along the Y direction in the named order, the first active region being adjacent in the longitudinal direction thereof to the fourth active region, the second active region being adjacent in the longitudinal direction thereof to the fifth active region, and the third active region being adjacent in the longitudinal direction thereof to the sixth active region. Assuming that the center position of the second lower electrode electrically connected to one end of the first active region in the longitudinal direction thereof is P1, the center position of the second lower electrode electrically connected to one end of the second active region in the longitudinal direction thereof is P2, the center positions of the second lower electrodes electrically connected respectively to one and the other ends of the third active region in the longitudinal direction thereof are P3a and P3b, the center position of the second lower electrode electrically connected to one end of the fourth active region in the longitudinal direction thereof is P4, the center position of the second lower electrode electrically connected to one end of the fifth active region in the longitudinal direction thereof is P5, and the center position of the second lower electrode electrically connected to one end of the sixth active region in the longitudinal direction thereof is P6, then there is preferably formed a hexagon having P1, P3a, P3b, P4, P5 and P6 as vertices, P2 being surrounded by the vertices of the hexagon.

In that case, it is preferable that a first rhombus having P1, P2, P3a and P3b as vertices is formed; a second rhombus having P2, P4, P5 and P6 as vertices is formed, the second rhombus being congruent with the first rhombus; a first parallelogram having P2, P3a, P3b and P6 as vertices is formed, and a second parallelogram having P1, P2, P4 and P5 as vertices is formed, the second parallelogram being congruent with the first parallelogram.

In one exemplary embodiment, the lower electrodes of capacitors have a laminated structure (stack structure) in which a plurality of electrodes are stacked. The upper-side electrodes of the capacitor lower electrodes are arranged while being displaced (shifted) a predetermined offset in a predetermined direction with respect to the lowermost-side electrodes of the capacitor lower electrodes. The lowermost-side electrodes of the capacitor lower electrodes and capacitance contact plugs (storage contact plugs) immediately below the lowermost-side electrodes can be directly connected to each other.

A DRAM (Dynamic Random Access Memory) provided with a 6 F² memory cell including a capacitor which uses such a laminated lower electrode as described above makes it possible to arrange the capacitor lower electrodes in a most densely packed state without having to provide any pad structures to connect the capacitor lower electrodes and the capacitance contact plugs immediately below the capacitor lower electrodes. Consequently, it is possible to manufacture a highly-integrated DRAM including a capacitor having large electrostatic capacitance at low costs.

Hereinafter, exemplary embodiments will be described with reference to the accompanying drawings.

As a first exemplary embodiment, a description will be given of an example in which the lower electrode of a capacitor has a laminated structure in which two cylinder-type electrodes are stacked.

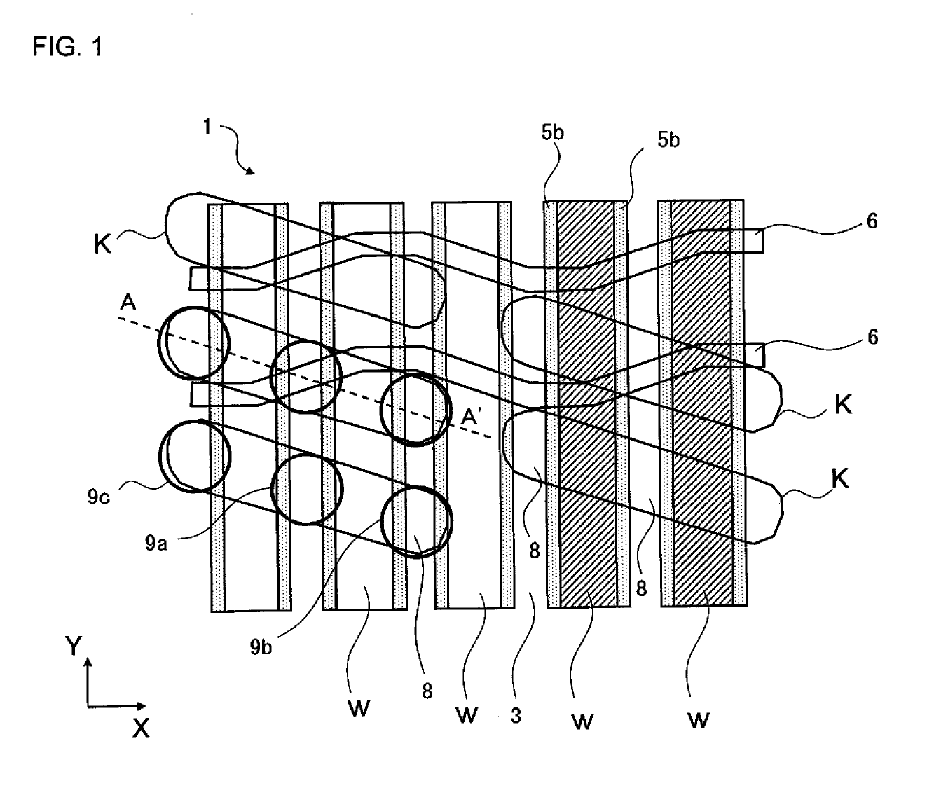

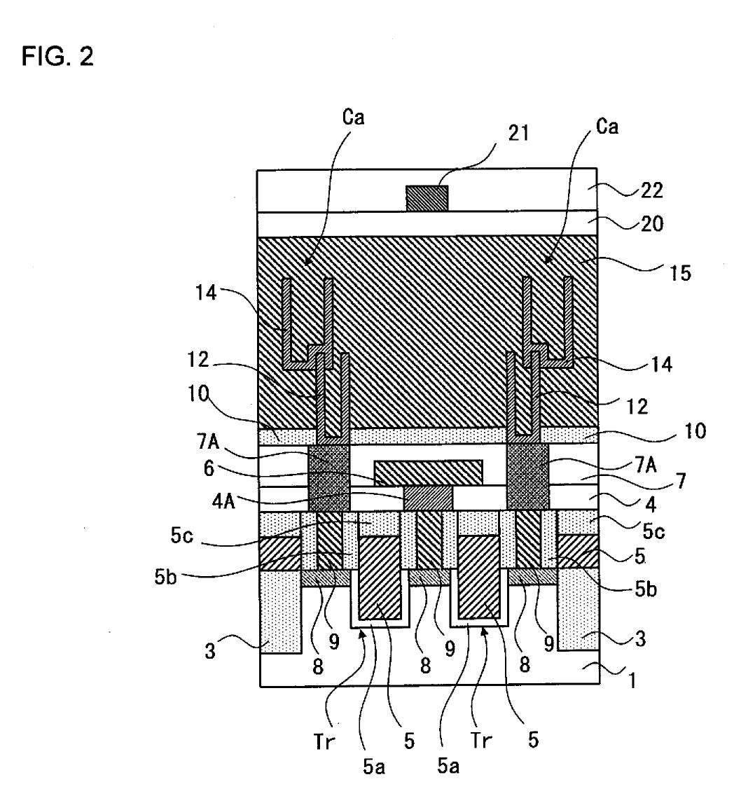

FIG. 1 is a plan view illustrating the structure of a DRAM memory cell part in the present exemplary embodiment, while FIG. 2 is a cross-sectional view taken along the line A-A′ of FIG. 1. In these figures, some components of the memory cell are omitted for ease of explanation. FIG. 1 is a plan view taken along a plane which cuts across gate electrodes 5 functioning as word lines W and sidewalls 5b in a planer direction, and perspectively illustrates active regions K and bit lines 6. Reference characters 9a, 9b and 9c denote the locations of substrate contact plugs to be connected to the active regions K of a semiconductor substrate 1. Reference numeral 6 denotes a bit line provided on an upper-layer side with respect to these substrate contact plugs. Note that the substrate contact plugs and bit lines are illustrated only for some active regions and are omitted for other active regions. In addition, hatching is not applied to gate electrodes shown to the left side of a central part of FIG. 1. Also note that for ease of explanation, the size of each part and a relationship in layout and dimension among constituent elements in these figures differ from those of an actual semiconductor device.

In the present exemplary embodiment, each memory cell includes a MOS transistor Tr for the memory cell and a capacitor (capacitance part) Ca connected to this MOS transistor Tr through a plurality of plugs 9 and 7A, as illustrated in FIG. 2.

The semiconductor substrate 1 is formed of silicon (Si) containing a P-type impurity having a predetermined concentration. Element-isolating regions 3 are formed in this semiconductor substrate 1. Each element-isolating region 3 is formed in a region other than an active region K by burying an insulating film, such as a silicon dioxide film (SiO₂), in a trench formed in the semiconductor substrate using a regular STI (Shallow Trench Isolation) method. As a result, the element-isolating region 3 surrounds each active region K and insulates and separates adjacent active regions from each other.

In the present exemplary embodiment, two bits of memory cells are arranged in one active region K.

Each active region K is elongate and reed-shaped and extends along a straight line in a belt-like manner, as illustrated in FIG. 1. Each active region K is arranged so that one longitudinal direction thereof faces diagonally downward right, i.e., the longitudinal direction forms a predetermined angle with the X direction. A plurality of active regions K arranged in this way are laid out along the Y direction, as well as along the longitudinal direction of the active regions K. A 6 F² layout of memory cells is formed on the basis of such a layout of active regions as described above.

Each active region K is arranged so as to intersect with two word lines. Impurity-diffused layers 8 are formed respectively in the both ends and the central part of each active region K. Each impurity-diffused layer 8 functions as a source/drain region of a MOS transistor Tr including a part of each word line on an active region as a gate electrode. Substrate contact plugs 9 (9a, 9b and 9c) are disposed immediately above the source/drain region (impurity-diffused layer).

Note that the shape and array direction of each active region K are not limited to the arrangement of FIG. 1, but may be modified to the extent that a layout of 6 F² memory cells is feasible.

As illustrated in FIG. 1, each bit line 6 extends in the shape of a polygonal line (bend line) along the horizontal (X) direction of the figure. In addition, a plurality of bit lines 6 are laid out at predetermined pitches in the vertical (Y) direction of the figure. Each bit line 6 includes portions intersecting with active regions K and portions extending along the longitudinal direction of each active region K (portions parallel to the longitudinal direction), and meanders along the X direction.

As illustrated in FIG. 1, each word line W extends in the shape of a straight line along the vertical (Y) direction of the figure. In addition, a plurality of word lines W are laid out at predetermined pitches in the horizontal (X) direction of the figure. Each word line W functions as a gate electrode 5 at a portion thereof intersecting with each active region K. In the present exemplary embodiment, each MOS transistor Tr is provided with a trench-type gate electrode. In this MOS transistor, a gate insulating film 5a is provided between the gate electrode 5 inside a trench formed in the semiconductor substrate and the semiconductor substrate 1, as illustrated in FIG. 2, thereby forming a channel in a side surface inside the trench. It is also possible to use a planar type MOS transistor in place of such a MOS transistor provided with a trench-type gate electrode as described above.

As illustrated in FIG. 2, impurity-diffused layers 8 functioning as source/drain regions are formed within each active region K partitioned by the element-isolating regions 3 in the semiconductor substrate 1. Adjacent impurity-diffused layers 8 within each active region K are separated from each other by each trench-type gate electrode 5.

Each gate electrode 5 is formed of a multilayer film composed of a polysilicon (polycrystalline) film and a metal-based conductive film, so as to protrude upward from the semiconductor substrate 1. The polysilicon film used for the gate electrode can be formed by letting the film contain an impurity, such as phosphorous, at the time of film formation using a CVD (Chemical Vapor Deposition) method. Alternatively, using an ion implantation method, an N-type or P-type impurity may be introduced into a polysilicon film which has been formed so as not to contain any impurities. As the metal-based conductive film used for the gate electrode, it is possible to use a high-melting point metal, such as tungsten (W), tungsten nitride (WN) or tungsten silicide (WSi), or a compound thereof.

A sidewall 5b made of silicon nitride (Si₃N₄) or the like is formed on a side surface of each gate electrode 5 and a gate-top insulating film 5c made of silicon nitride or the like is formed on an upper surface of each gate electrode 5, thereby protecting a protruding part of each gate electrode 5.

Each impurity-diffused layer 8 is formed by introducing, for example, phosphorous as an N-type impurity into the semiconductor substrate 1 containing a P-type impurity.

As illustrated in FIG. 2, substrate contact plugs 9 are formed so as to come into contact with the impurity-diffused layers 8. The substrate contact plugs 9 are disposed in positions denoted by reference characters 9a, 9b and 9c, as illustrated in FIG. 1. Each substrate contact plug 9 can be formed by forming a hole in a first interlayer insulating film (not illustrated) made of silicon oxide or the like and formed on the semiconductor substrate and filling, for example, phosphorous-containing polysilicon in this hole. The width of each substrate contact plug 9 in the horizontal direction (X) direction of the figure is defined by the sidewalls 5b of adjacent word lines W (gate electrodes 5). The substrate contact plug 9 thus has a self-aligned structure.

As illustrated in FIG. 2, a second interlayer insulating film 4 is formed so as to cover the gate-top insulating films 5c, the sidewalls 5b, the substrate contact plugs 9, and the first interlayer insulating film (not illustrated.

A bit line contact plug 4A is formed so as to penetrate the second interlayer insulating film 4. The bit line contact plug 4A is located in a position denoted by reference character 9a shown in FIG. 1 and is in electrical conduction with a substrate contact plug 9 immediately below the bit line contact plug 4A. The bit line contact plug 4A is formed by depositing tungsten (W) or the like on a barrier film (TiN/Ti) made of a laminated film of titanium (Ti) and titanium nitride (TiN). A bit line 6 is formed so as to connect to the bit line contact plug 4A. The bit line 6 is formed of a laminated film made of tungsten nitride (WN) and tungsten(W). A third interlayer insulating film 7 is formed so as to cover the bit line 6.

Capacitance contact plugs 7A are formed through the third interlayer insulating film 7 and the second interlayer insulating film 4, so as to connect to the substrate contact plugs 9. The capacitance contact plugs 7A are disposed immediately above the substrate contact plugs 9 in positions denoted by reference characters 9b and 9c shown in FIG. 1. A fourth interlayer insulating film 10 made of silicon nitride is formed so as to cover the upper surfaces of the capacitance contact plugs 7A.

The lower electrode (parts 12 and 14) of each capacitor Ca is formed through the fourth interlayer insulating film 10, so as to connect to a capacitance contact plug 7A. Each capacitor Ca has a structure in which a capacitance insulating film (not illustrated) is sandwiched between the lower electrode (parts 12 and 14) and an upper electrode 15. The lower electrode of each capacitor Ca has a laminated structure in which a lower-layer part 12 and an upper-layer part 14 are stacked. Both the lower-layer part 12 and the upper-layer part 14 are cylindrical (hollow) in shape. The lower-layer part 12 of each capacitor lower electrode is directly connected to each capacitance contact plug 7A.

A fifth interlayer insulating film 20 is formed on the capacitors Ca. An upper-layer interconnect layer 21 made of aluminum (Al), copper (Cu) or the like is formed on the fifth interlayer insulating film 20. In addition, a surface protection film 22 covering the upper-layer interconnect layer 21 is further formed on the fifth interlayer insulating film 20.

Note that capacitors for storage operation are not disposed in unillustrated regions other than regions for the memory cell parts of a DRAM (peripheral circuit region and the like). An interlayer insulating film (not illustrated) made of silicon oxide or the like is formed on the fourth interlayer insulating film 10.

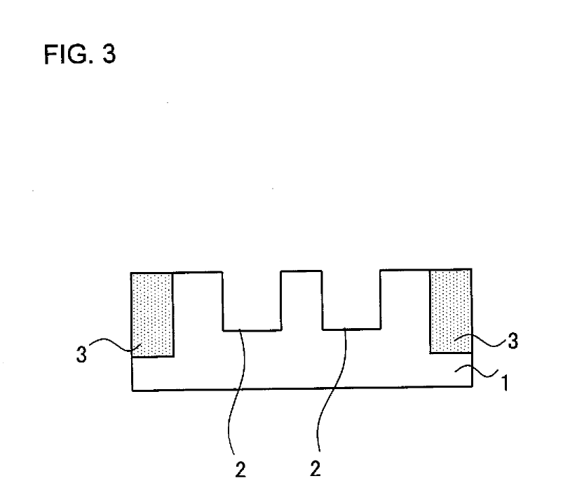

Next, one example of a method for manufacturing the semiconductor memory device described by referring to FIGS. 1 and 2 will be described with reference to FIGS. 3 to 11. FIGS. 3 to 11 are schematic cross-sectional views corresponding to the line A-A′ of FIG. 1 illustrating a memory cell part.

First, as illustrated in FIG. 3, element-isolating regions 3 are formed on the principal surface of a semiconductor substrate 1 made of P-type silicon to form active regions K partitioned by the element-isolating regions 3. Each element-isolating region 3 is formed by forming a trench in the semiconductor substrate according to a regular STI method and filling this trench with an insulating film, such as silicon dioxide (SiO₂). The active regions K are disposed as illustrated in FIG. 1.

Next, as illustrated in FIG. 3, trenches 2 for the gate electrodes of a MOS transistor Tr are formed to a depth of approximately 200 nm. Each trench 2 is formed by forming a resist pattern on the semiconductor substrate 1 using a photolithography technique and anisotropically etching the semiconductor substrate using this resist pattern as a mask.

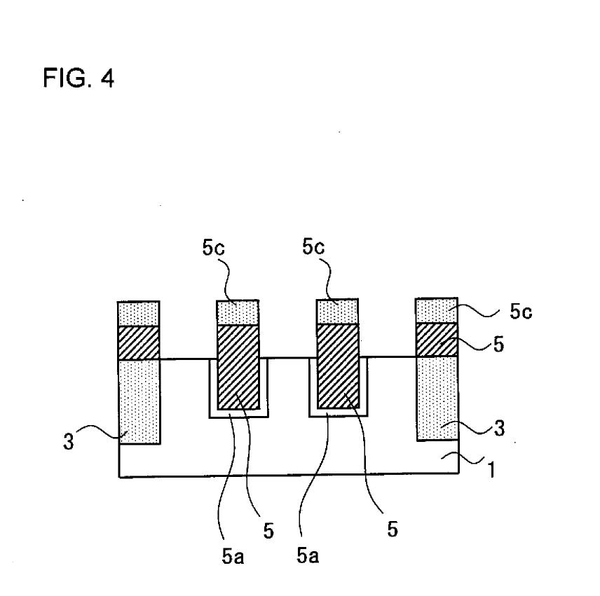

Next, a surface of the semiconductor substrate 1 is oxidized using a thermal oxidation method. Then, an approximately 4 nm-thick silicon oxide film is formed on the semiconductor substrate, including the inside of each trench 2. Silicon oxide films left inside the trenches 2 after the formation of later-described gate electrodes serve as gate insulating films 5a (FIG. 4). As the gate insulating film, a laminated film of silicon oxide and silicon nitride, or a high-K film (high-dielectric constant film) may be used.

After this, a polysilicon film containing an N-type impurity is deposited on the gate insulating films 5a to a thickness of approximately 100 nm by a CVD method using monosilane (SiH₄) and phosphine (PH₃) as raw material gases. At this time, the polysilicon film is set to such a thickness that the inside of each trench 2 for a gate electrode is completely filled with the polysilicon film. Alternatively, a polysilicon film not containing an impurity may be formed, and a desired impurity such as phosphorous may be introduced into the polysilicon film in a later step using an ion implantation method.

Next, a metal-based conductive film made of a high-melting point metal, such as tungsten, tungsten nitride or tungsten silicide, or a compound thereof is deposited on the above-described polysilicon film to a thickness of approximately 50 nm using a sputtering method. These polysilicon film and metal-based conductive film are made to go through later-described steps, so as to be processed into gate electrodes 5 having predetermined patterns.

Next, an insulating film 5c made of silicon nitride is deposited on the above-described metal-based conductive film to a thickness of approximately 70 nm by a plasma CVD method using monosilane and ammonia (NH₃) as raw material gases.

Next, a resist pattern for gate electrode formation is formed on the insulating film 5c using a photolithography technique. Using this resist pattern as a mask, anisotropic etching is performed to pattern the insulating film 5c. After the removal of the resist pattern, anisotropic etching is performed using a pattern formed of the insulating film 5c as a hard mask to pattern the metal-based conductive film and polysilicon film, as illustrated in FIG. 4, thereby forming the gate electrodes 5. At the time of etching for gate electrode formation, the silicon oxide film is left inside the trenches 2, and the silicon oxide film may be left on the semiconductor substrate 1 outside the trenches 2. The gate electrodes 5 thus formed function as word lines W, as illustrated in FIG. 1. Note that in the figure, the metal-based conductive film and the polysilicon film constituting the gate electrodes 5 are illustrated in the same way of hatching with no distinction.

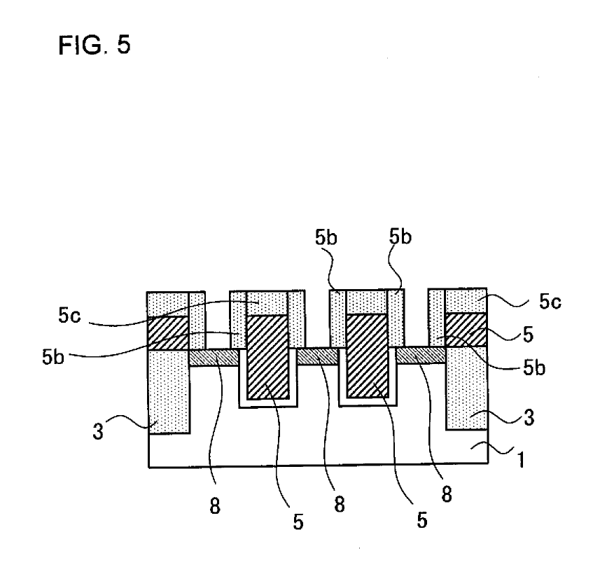

Next, as illustrated in FIG. 5, phosphorous is ion-implanted as an N-type impurity into a surface of the semiconductor substrate 1 to form impurity-diffused layers 8 in parts of the active region not covered with the gate electrodes 5.

After this, a silicon nitride film is deposited to a thickness of approximately 20 to 50 nm on the entire surface of the structure being fabricated using a CVD method. The silicon nitride film is then etched back to form sidewalls 5b on the side surfaces of the gate electrodes 5, as illustrated in FIG. 5.

Next, a first interlayer insulating film (not illustrated) made of silicon oxide or the like is formed using a CVD method, so as to cover the gate-top insulating films 5c and the sidewalls 5b. After that, a surface of the first interlayer insulating film is polished using a CMP (Chemical Mechanical Polishing) method, in order to planarize the irregularity of the first interlayer insulating film resulting from the protruding parts of the gate electrodes 5. This polishing is stopped at the moment the upper surfaces of the gate-top insulating films 5c become exposed.

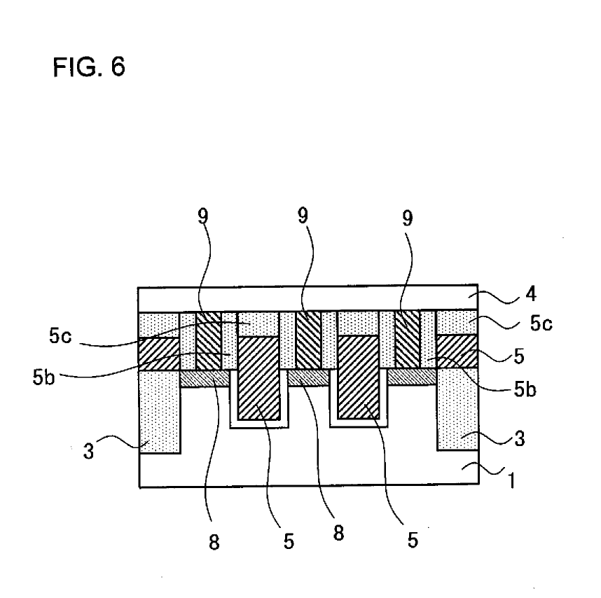

After this, substrate contact plugs 9 to be connected to the impurity-diffused layers 8 are formed, as illustrated in FIG. 6. Specifically, a resist pattern having openings in positions denoted by reference characters 9a, 9b and 9c shown in FIG. 1 is formed first using a lithography technique. Then, using this resist pattern as a mask, anisotropic etching is performed to form contact holes penetrating the first interlayer insulating film. Each contact hole is formed between adjacent gate electrodes 5 by means of self-alignment which takes advantage of a difference in etching rate between the insulating films 5c and 5b formed of silicon nitride and the interlayer insulating film formed of silicon oxide. After this, a phosphorous-containing polysilicon film is deposited using a CVD method. Then, this polysilicon film is polished using a CMP method to remove excess parts of the polysilicon film outside the contact holes. As a result, there are formed the substrate contact plugs 9 made of the polysilicon film filled in the contact holes.

After this, a second interlayer insulating film 4 made of silicon oxide is formed to a thickness of, for example, approximately 600 nm using a CVD method, so as to cover the substrate contact plugs 9, the gate-top insulating films 5c and the sidewalls 5b. After that, a surface of the second interlayer insulating film 4 is polished and planarized using a CMP method until a thickness of, for example, approximately 300 nm is reached. Consequently, the first interlayer insulating film and the second interlayer insulating film 4 coalesce with each other.

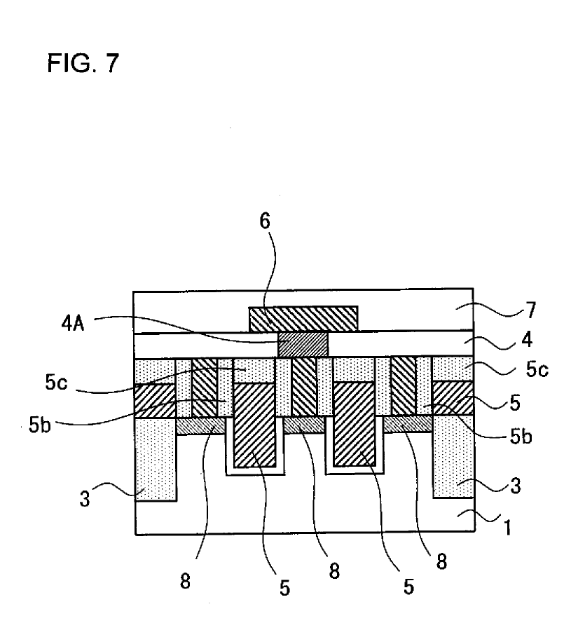

Next, a hole is formed in a position denoted by reference character 9a shown in FIG. 1, so as to penetrate the second interlayer insulating film 4, thereby exposing a surface of each substrate contact plug 9. A conductive film, in which a film of tungsten (W) is laminated on a barrier film made of TiN/Ti or the like is deposited so as to fill this hole. Then, a surface of the conductive film is polished using a CMP method to remove excess parts of the conductive film outside the hole, thereby forming a bit line contact plug 4A illustrated in FIG. 7.

Next, a bit line 6 is formed so as to connect to the bit line contact plug 4A, as illustrated in FIG. 7. Then, a third interlayer insulating film 7 made of silicon oxide or the like is formed so as to cover the bit line 6.

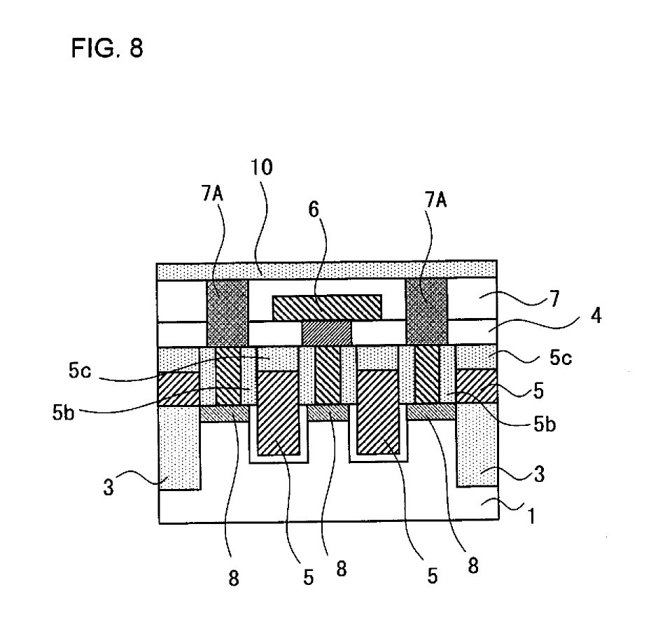

Next, contact holes are formed in positions denoted by reference characters 9b and 9c shown in FIG. 1, so as to penetrate the second interlayer insulating film 4 and the third interlayer insulating film 7, thereby exposing surfaces of the substrate contact plugs 9. A conductive film, in which a film of tungsten (W) is laminated on a barrier film made of TiN/Ti or the like, is deposited so as to fill these contact holes. Then, a surface of the conductive film is polished using a CMP method to remove excess parts of the conductive film outside the contact holes, thereby forming capacitance contact plugs 7A illustrated in FIG. 8.

After this, as illustrated in FIG. 8, a fourth interlayer insulating film 10 made of silicon nitride is formed on the third interlayer insulating film 7 to a thickness of, for example, 60 nm, so as to cover the capacitance contact plugs 7A.

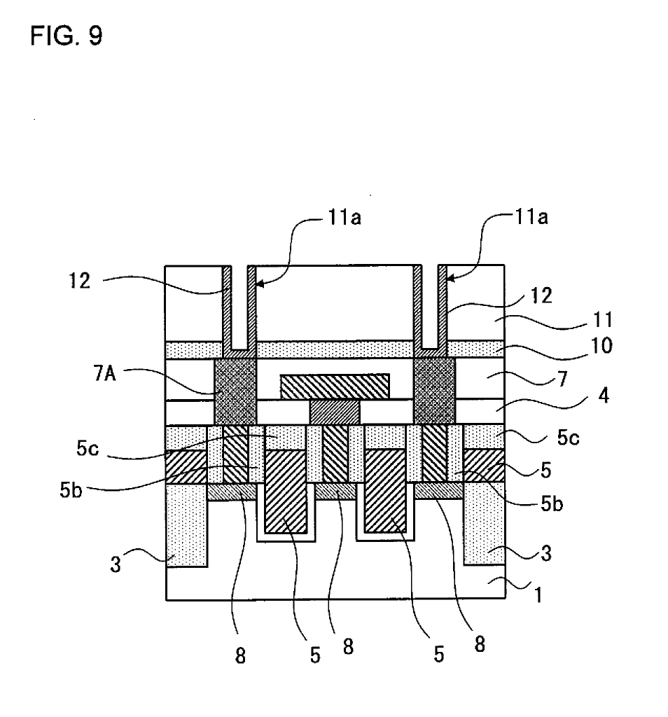

Next, as illustrated in FIG. 9, a first sacrificial interlayer insulating film 11 made of silicon oxide or the like is formed to a thickness of, for example, 1 μm. After this, holes 11a for forming the lower-layer parts 12 of capacitor lower electrodes are formed in the first sacrificial interlayer insulating film 11 using photolithography and anisotropic dry etching techniques, thereby exposing the upper surfaces of the capacitance contact plugs 7A. Then, the lower-layer parts 12 of the capacitor lower electrodes are formed inside the holes 11a.

The lower-layer parts 12 of the capacitor lower electrodes can be formed in the following way. First, a titanium nitride film is formed to such a thickness as not to fill the holes 11a. Next, parts of the titanium nitride film outside the holes 11a are removed using a dry etching method or a CMP method. The lower-layer parts 12 of the capacitor lower electrodes are thus formed by leaving the titanium nitride film only on the inner walls of the holes 11a. As a material of the capacitor lower electrodes, it is also possible to use a metal film other than the titanium nitride film. A protection material, such as a photoresist film, may be filled in the holes 11a prior to removing the titanium nitride using a dry etching method, in order to protect the bottom faces of the holes 11a. This protection material is removed after dry etching.

In a planar layout, the center positions of the lower-layer parts 12 of the capacitor lower electrodes may not be aligned with the center positions of the capacitance contact plugs 7A. If the lower-layer part 12 of each capacitor lower electrode is disposed in the manner that the bottom face area thereof does not fall within but runs off the top face area of each capacitance contact plug 7A, the overetched amount (etching time) of dry etching at the time of forming each hole 11a is adjusted, so that the hole 12 does not reach the bit line on the lower-layer side. Consequently, it is possible to prevent the lower-layer part 12 of each capacitor lower electrode and the bit line from short-circuiting with each other.

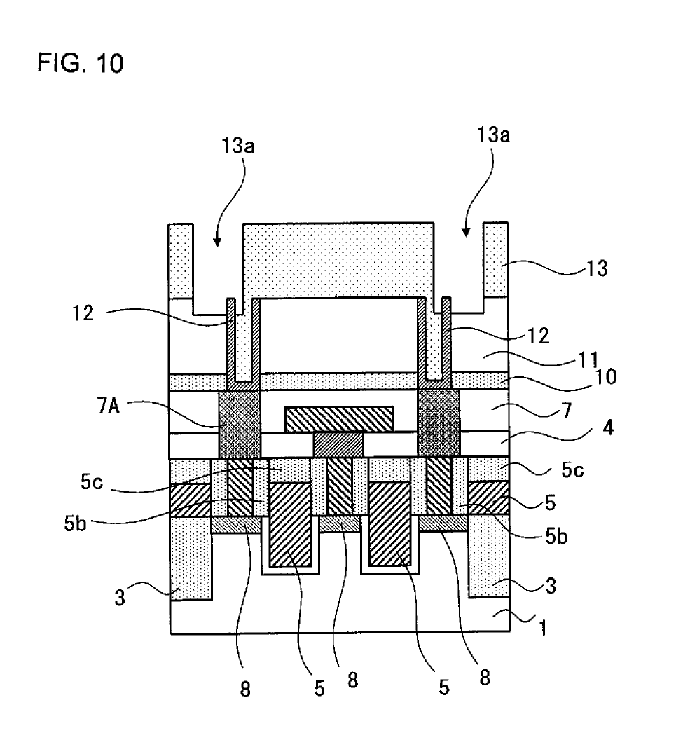

Next, as illustrated in FIG. 10, a second sacrificial interlayer insulating film 13 made of silicon oxide or the like is deposited to a thickness of, for example, 1 μm. After this, holes 13a for forming the upper-layer parts 14 of capacitor lower electrodes are formed in the second sacrificial interlayer insulating film 13 using photolithography and dry etching techniques, thereby exposing part of the lower-layer part 12 of each capacitor lower electrode.

Next, the upper-layer part 14 of each capacitor lower electrode is formed inside each hole 13a in the same way as the lower-layer part 12 of each capacitor lower electrode.

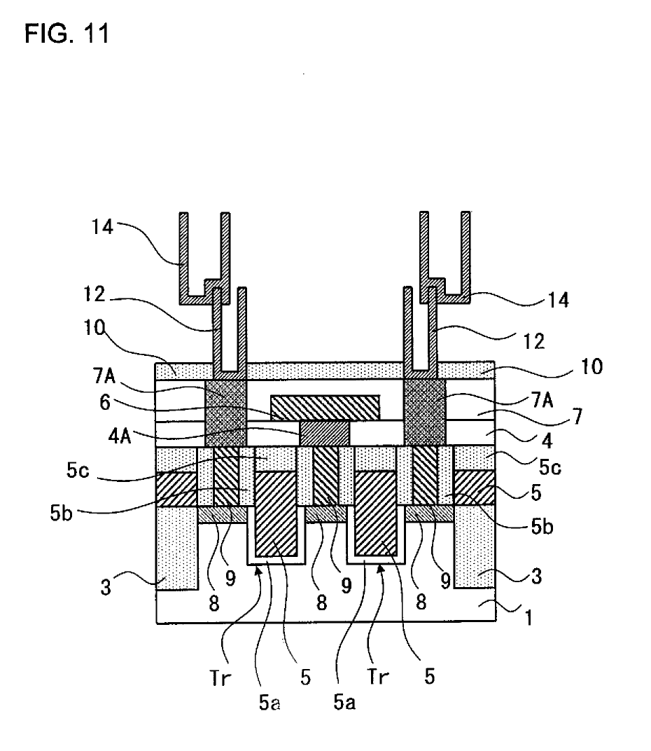

Next, as illustrated in FIG. 11, wet etching using hydrofluoric acid (HF) is performed to remove the first sacrificial interlayer insulating film 11 and the second sacrificial interlayer insulating film 13 of each memory cell part, thereby exposing the upper-layer part 14 and the lower-layer part 12 of each capacitor lower electrode. The fourth interlayer insulating film 10 made of silicon nitride functions as a stopper film at the time of this wet etching, thereby protecting transistors and other components positioned on the lower-layer side. Note that regions, other than the memory cell parts, which also need to be protected at the time of this wet etching are previously covered with a silicon nitride film.

Next, a capacitance insulating film (not illustrated) is formed so as to cover the exposed surfaces of each capacitor lower electrode (parts 12 and 14). As the capacitance insulating film, it is possible to use a high-K film, such as hafnium oxide (HfO₂), zirconium oxide (ZrO₂) or aluminum oxide (Al₂O₃), or a laminated film including such a high-K film.

Next, as illustrated in FIG. 2, a capacitor upper electrode 15 is formed using an electrically conductive material, such as titanium nitride. The upper electrode 15 may also be formed using a laminated structure including a titanium nitride layer and a polysilicon layer. A structure in which the capacitance insulating film is sandwiched by the capacitor lower electrode (parts 12 and 14) and the capacitor upper electrode 15 forms each capacitor Ca.

Next, a fifth interlayer insulating film 20 made of silicon oxide or the like is formed. In each memory cell part, a lead-out contact plug (not illustrated) for providing a potential to the capacitor upper electrode 15 is formed in the fifth interlayer insulating film 20.

After this, an upper-layer interconnect 21 is formed using an interconnect material, such as aluminum (Al) or copper (Cu). Then, a surface protection film 22 is formed using a protection material, such as silicon oxynitride (SiON), thereby completing DRAM memory cell parts.

In the present exemplary embodiment described heretofore, the upper-layer part 14 of each capacitor lower electrode is disposed out of alignment with the lower-layer part 12, as illustrated in FIG. 2. Consequently, it is possible to form a capacitor having large electrostatic capacitance in a simple and convenient manner without having to provide any pad structure between the lower-layer part 12 and the upper-layer part 14. In addition, it is possible to form a highly-integrated DRAM.

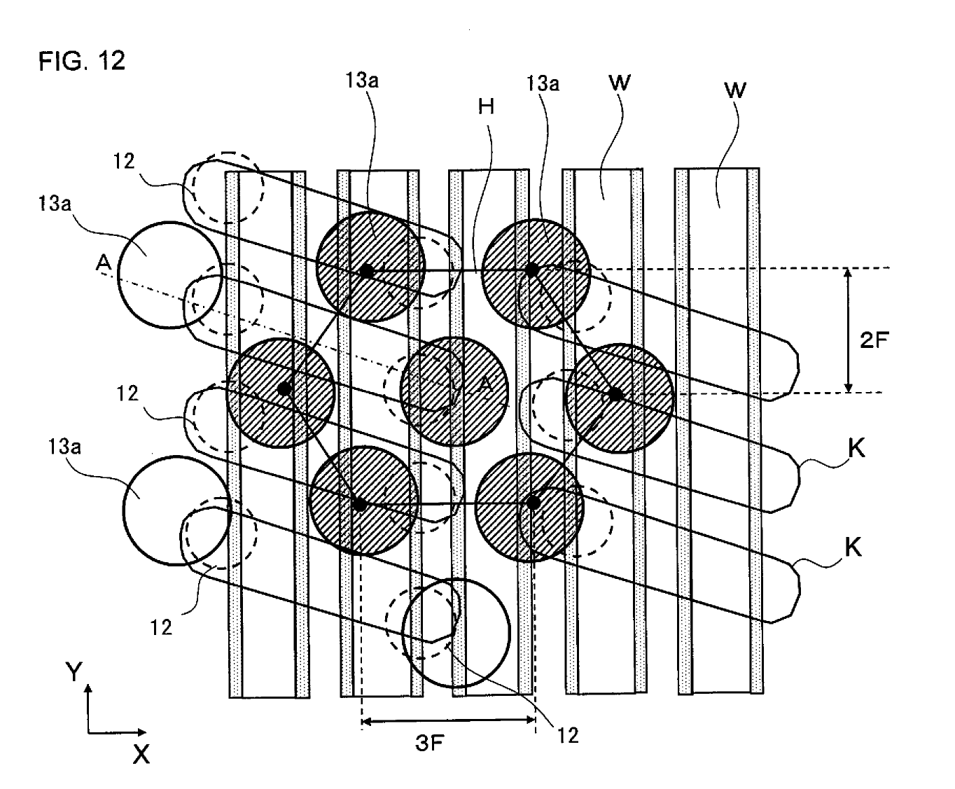

FIG. 12 illustrates an arrangement of holes 13a corresponding to the upper-layer parts 14 of capacitor lower electrodes. Specifically, FIG. 12 shows a positional relationship of the holes 13a with word lines W, sidewalls, active regions K, and the lower-layer parts 12 (corresponding to the holes 11a) of capacitor lower electrodes. Bit line contact plugs, bit lines, capacitance contact plugs, and substrate contact plugs are omitted from the figure.

The upper-layer part 14 of each capacitor lower electrode formed inside a hole 13a need not necessarily overlap with the entire outer circumference of the lower-layer part 12 of the capacitor lower electrode, but may partially overlap with the outer circumference. For example, the upper-layer part 14 may be connected to a part on the outer circumference of the lower-layer part 12, as illustrated in FIG. 11.

In a 6 F² memory cell to which such a structure as described above has been applied, it is possible to place an arrangement of capacitors in a most densely packed state by appropriately disposing the upper-layer parts 14 (corresponding to holes 13a) of capacitor lower electrodes. That is, adjacent six holes 13a are arranged so that the center positions thereof form a hexagon H illustrated in FIG. 12. In addition, one of holes 13a forming another hexagon H is arranged inside this hexagon H. If a size F (Feature Size) of a design rule which defines the size of the 6 F² memory cell is used, a center-to-center distance of the upper-layer parts 14 of adjacent lower electrodes along the X direction is represented by 3 F, and the pitch along the Y direction of arrays of upper-layer parts 14 along the X direction is represented by 2 F, as illustrated in FIG. 12. Note that the size F is a value corresponding to the minimum processing dimension in a manufacturing process.

Now, a most densely packed arrangement will be described hereinafter in detail. A most densely packed arrangement refers to an arrangement in which the outer circumferential length (surface area) of each capacitor lower electrode can be made as large as possible, while securing a space (isolation width) whereby short-circuiting between adjacent capacitor lower electrodes can be prevented.

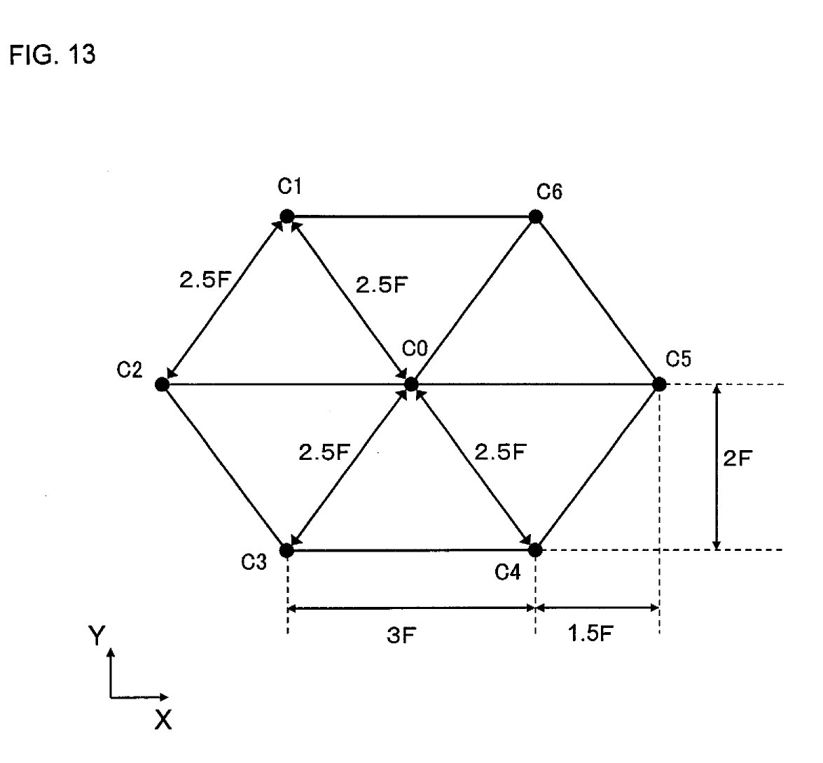

An ideal closest-packing arrangement is an arrangement in which the hexagon H illustrated in FIG. 12 is an equilateral hexagon. This arrangement is difficult to achieve, however, in a 6 F² layout. Hence, by arranging electrodes as illustrated in FIG. 13, it is possible to make the outer circumferential length of each capacitor lower electrode as large as possible. Symbols C0 and C1 to C6 in FIG. 13 denote the centers of the upper-layer parts of capacitor lower electrodes when the planar shapes thereof are circular. Whereas a C3-to-C4 distance is 3F, a C0-to-C3 distance and a C0-to-C4 distance are 2.5 F. A pitch along the Y direction of arrays of the upper-layer parts of lower electrodes along the X direction is 2 F. Arranging electrodes in this way is referred to as a most densely packed arrangement in the present exemplary embodiment.

If capacitor lower electrodes are placed in the positions of capacitance contact plugs (corresponding to the positions denoted by reference characters 9b and 9c shown in FIG. 1) with no displacement therefrom (offset=0), a distance between adjacent capacitor lower electrodes becomes nonuniform. Accordingly, if an electrode size is set according to a part of layout narrowest in interelectrode pitch, electrodes having a short outer circumferential length are formed also in parts of layout wide in interelectrode pitch. Thus, it is not possible to obtain sufficiently large electrostatic capacitance.

In the present exemplary embodiment, it is possible to reduce the nonuniformity of a pitch between the upper-layer parts 14 of adjacent lower electrodes by arranging the upper-layer part 14 of each capacitor lower electrode out of alignment with each lower-layer part 12. Consequently, it is possible to make larger the outer circumferential length of the upper-layer part 14 of each lower electrode, while preventing adjacent lower electrodes from short-circuiting with each other. In addition, it is possible to make the sidewalls of the lower-layer part 12 of each lower electrode also function as capacitor lower electrodes. As a result, it is possible to form a highly-integrated DRAM provided with capacitors having large electrostatic capacitance.

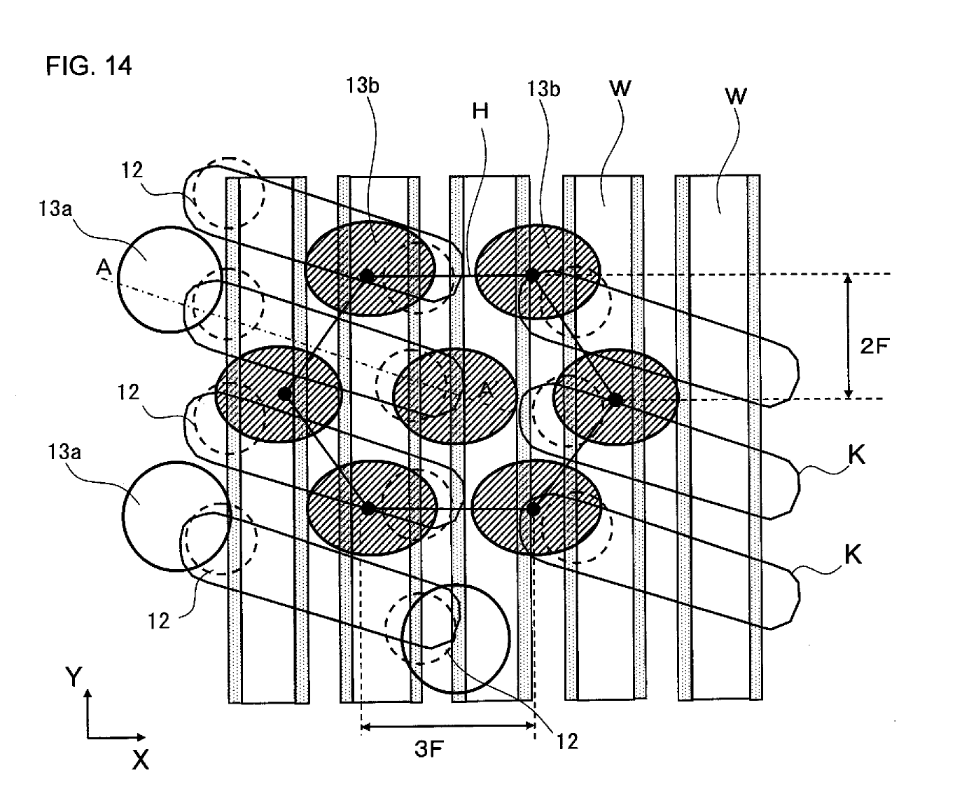

FIG. 14 illustrates a modified example of the example illustrated in FIG. 12. In the 6 F² layout of the present exemplary embodiment, a distance (3 F) between electrodes (for example, a C3-to-C4 distance) adjacent to each other in the X direction is longer than a pitch along the Y direction (2 F), as illustrated in FIG. 13. Accordingly, it is possible to more effectively carry out electrode arrangement by shaping the upper-layer part 14 of each capacitor lower electrode into an ellipse, as illustrated in FIG. 14. In FIG. 14, each reference character 13b denotes a position in which a hole corresponding to the upper-layer part 14 of each lower electrode is to be formed. The upper-layer part 14 of each lower electrode is formed inside this hole 13b. The center-point positions of ellipses corresponding to the respective holes 13b are arranged as described earlier with reference to FIG. 13. By arranging the long axes of the ellipses along the X direction, it is possible to form electrodes larger in outer circumferential length than circular electrodes, while preventing adjacent lower electrodes from short-circuiting with each other. Alternatively, the ellipses may be arranged so that the long-axis direction thereof forms an angle with the X-axis direction. Still alternatively, rectangular upper-layer parts of lower electrodes may be formed by using a double patterning technique at the time of forming holes (13a and 13b) for the upper-layer parts of lower electrodes. In the present invention, the planar shape of the upper-layer part 14 of each lower electrode is not limited in particular. By arranging the center position of the upper-layer part 14 of each lower electrode out of alignment with the center position of each lower-layer part 12, it is possible to attain the effect of increasing the electrostatic capacitance of a capacitor.

The lower-layer part 12 of each lower electrode may be arranged by taking into consideration a positional relationship between each capacitance contact plug 7A and the upper-layer part 14 of each lower electrode, so that an excellent state of connection is ensured for both the contact plug and the upper-layer part.

Next, a description will be given specifically of a shift direction and an offset in the arrangement of each upper-layer part 14 with respect to the lower-layer part 12 of each capacitor lower electrode.

The size F, as described above, is a numeric value of a design rule which defines the size of a memory cell and can be set to, for example, 50 nm. According to a 6 F² layout, gate electrode interconnects constituting word lines can be arranged, so as to be parallel to one another at a width of 1 F and a pitch of 1 F, exclusive of the widths of sidewalls formed on sidewall parts.

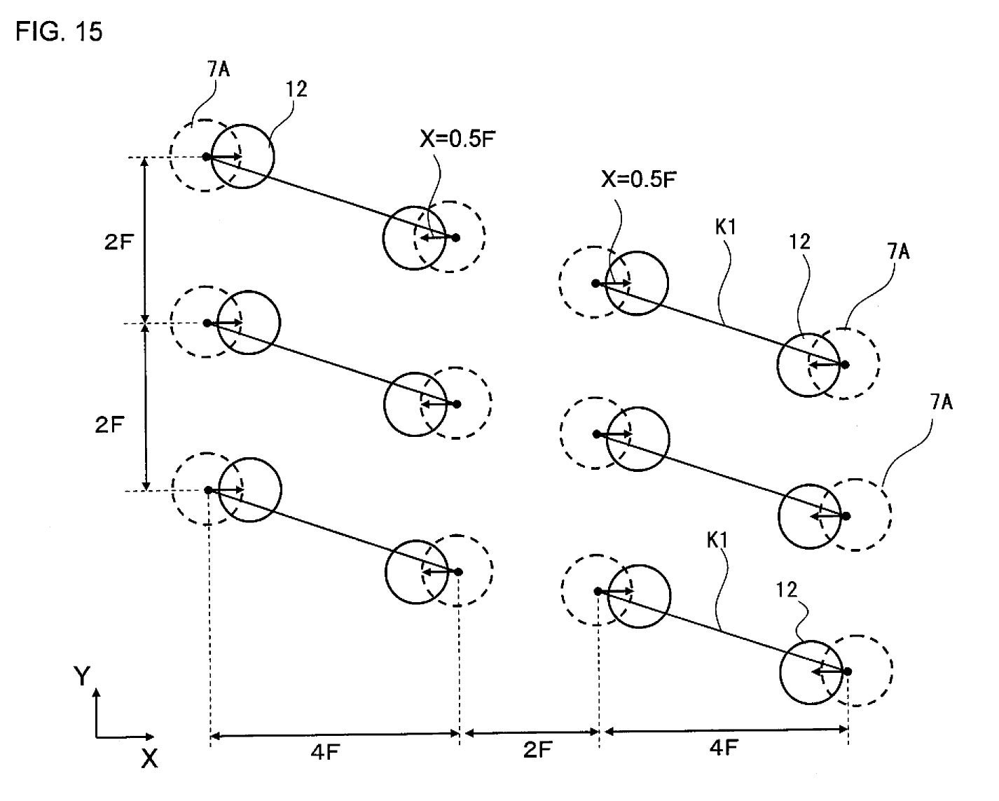

The lower-layer part 12 of each capacitor lower electrode is arranged out of alignment with each capacitance contact plug 7A, as illustrated in FIG. 15. Each straight line K1 in the figure corresponds to one partitioned active region K. Each capacitance contact plug 7A is disposed at one and the other ends of one active region (corresponding to positions denoted by reference characters 9b and 9c shown in FIG. 1), respectively. The center-to-center distance of two capacitance contact plugs 7A is set to 4 F as a distance along the X direction (X component). The center-to-center distance of adjacent capacitance contact plugs 7A between active regions adjacent to each other in the extending direction thereof is set to 2 F as a distance along the X direction (X component). In addition, the center-to-center distance of capacitance contact plugs 7A adjacent to each other in the Y direction (Y component) is set to 2F. In order to attain such an arrangement as described above, each active region is disposed so that the extending direction thereof (longitudinal direction of each straight line K1) forms an angle of approximately 18° with the X direction.

As illustrated in FIG. 15, the lower-layer part 12 of each capacitor lower electrode is disposed with a displacement of 0.5 F in the X direction from the center position of each capacitance contact plug 7A. The lower-layer part 12 is not displaced in the Y direction, however. The shift direction of the lower-layer part 12 of each lower electrode is reversed horizontally along the X direction in an alternate manner, as shown by arrows. That is, in FIG. 15, the leftmost array of the lower-layer parts 12 of lower electrodes is displaced 0.5 F to the right and an array of lower-layer parts 12 on the right of the leftmost array is displaced 0.5 F to the left. Thereafter, this arrangement is repeated.

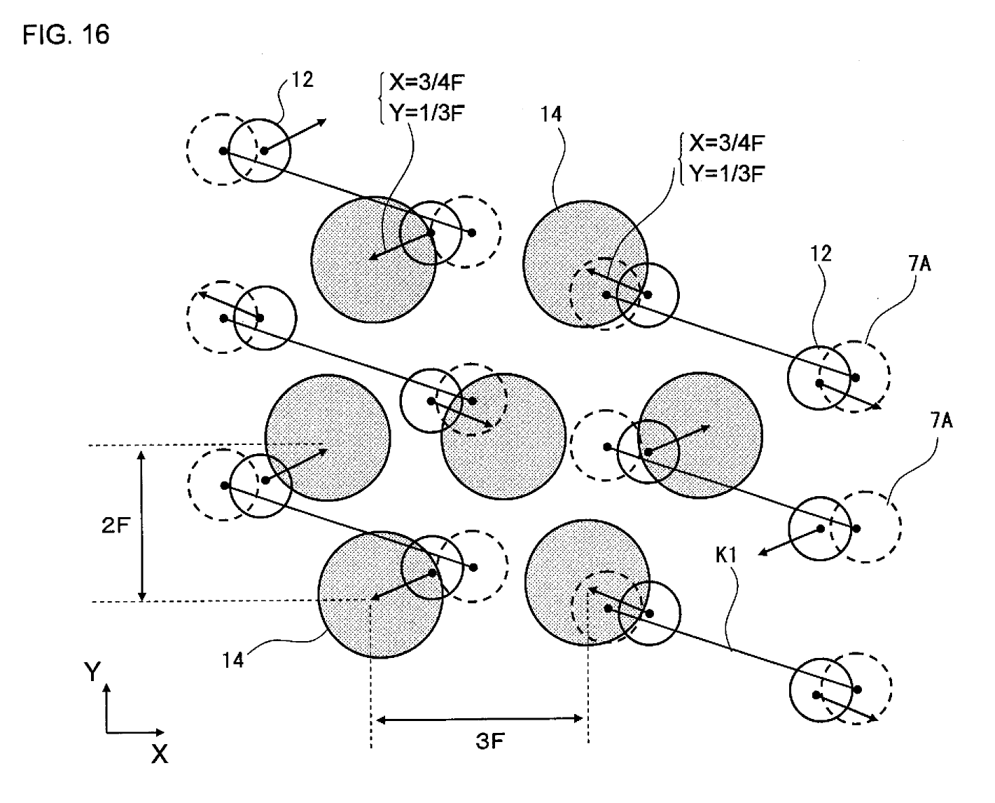

As illustrated in FIG. 16, the upper-layer part 14 of each capacitor lower electrode is arranged so as to be displaced as described below with respect to the center position of the lower-layer part 12 of each lower electrode. The offset of the center position of the upper-layer part 14 of each lower electrode is set to ¾ F (=0.75 F) along the X direction (X component) and to ⅓ F (=0.33 F) along the Y direction (Y component). The shift direction of the upper-layer part 14 of each lower electrode is faced upward, as shown by an arrow, with respect to the leftmost array of the lower-layer parts 12 of lower electrodes. In addition, the shift direction is reversed horizontally along the Y direction in an alternate manner. The upper-layer part 14 of each lower electrode is displaced downward with respect to an array of the lower-layer parts 12 of lower electrodes second from the leftmost array. In addition, the shift direction is reversed horizontally along the Y direction in an alternate manner. Thereafter, this arrangement is repeated. Note that as described earlier, the planar shape of the upper-layer part 14 of each lower electrode may have a shape other than a circle.

By disposing the electrodes as described above, it is possible to arrange the center positions of the upper-layer parts 14 of lower electrodes, as represented by the hexagon H described earlier using FIG. 13.

Next, a description will be given of a second exemplary embodiment which is a modified example of the above-described first exemplary embodiment.

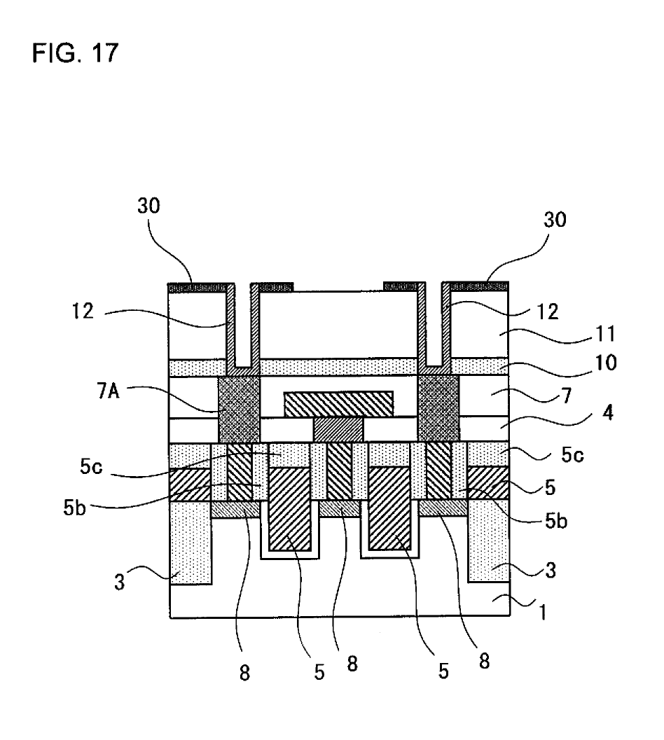

In the second exemplary embodiment, a support film 30 made of silicon nitride is formed on a first sacrificial interlayer insulating film 11, and then holes 11a are formed therein. The lower-layer part 12 of each capacitor lower electrode is formed on the inner wall of each of these holes 11a. Then, the support film 30 is patterned to obtain a structure illustrated in FIG. 17.

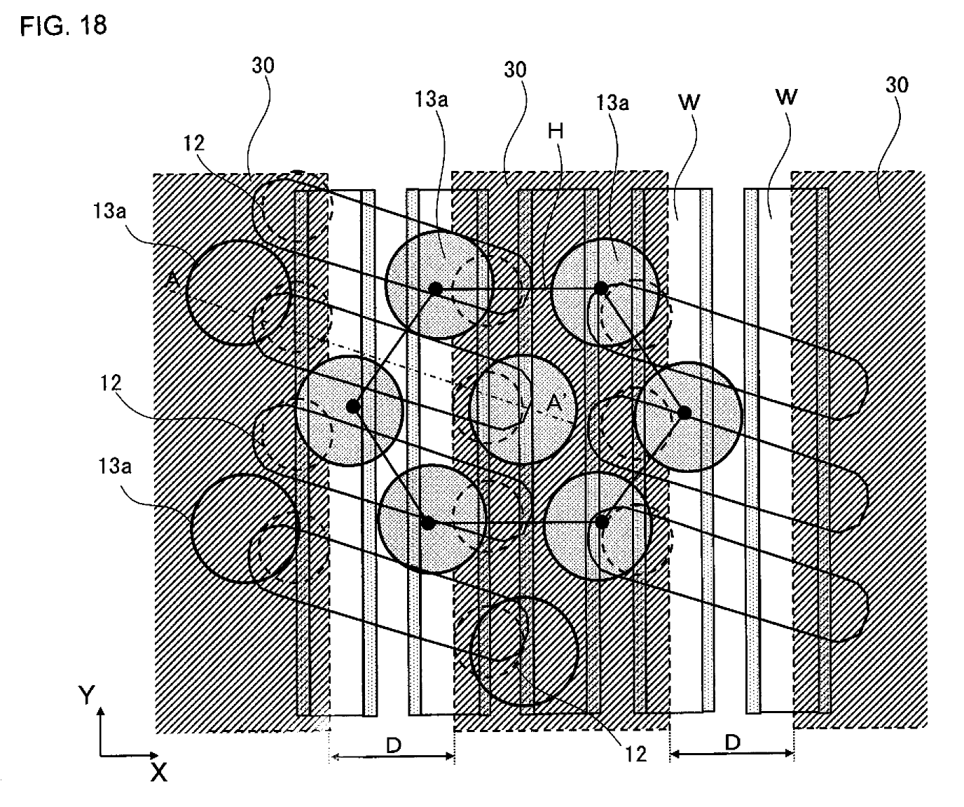

The post-patterning support film 30 will be described using FIG. 18. FIG. 18 illustrates an arrangement of the support film 30 with respect to the layout illustrated in FIG. 12. The post-patterning support film 30 has belt-like patterns extending in the Y direction. These belt-like patterns are laid out in parallel with one another, so as to be apart at a pitch D. The support film 30 need not necessarily completely cover the upper-end outer circumference of the lower-layer part 12 of each capacitor lower electrode. Alternatively, the structure may be such that only part of the upper-end outer circumference of the lower-layer part 12 is covered with the support film 30. The support film 30 is disposed so as to extend up to the ends of each memory cell region. Note that in FIG. 18, the support film 30 covers a circular region showing the lower-layer part 12 of each lower electrode. In practice, however, the support film 30 is removed when the holes 11a are formed and, therefore, does not cover the circular region, as illustrated in FIG. 17.

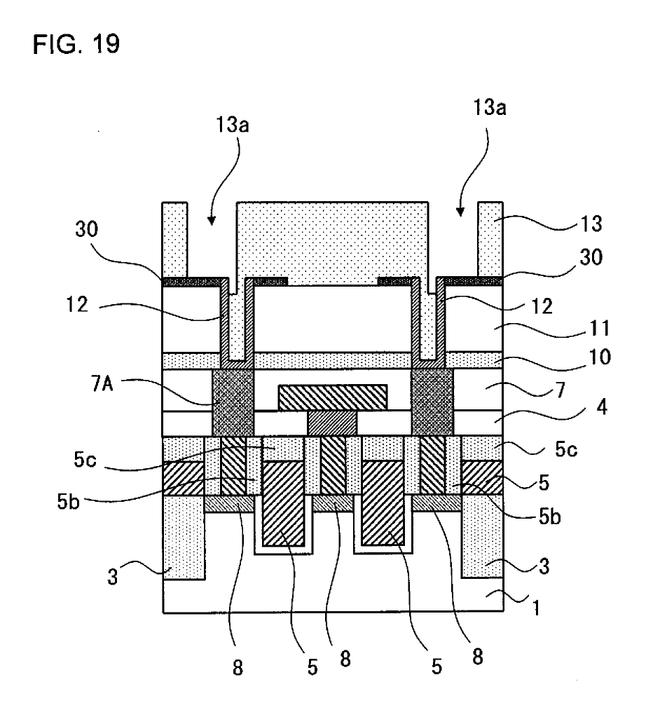

Next, as illustrated in FIG. 19, a second sacrificial interlayer insulating film 13 made of a silicon oxide film is formed. Then, holes 13a are formed in the second sacrificial interlayer insulating film 13 using lithography and dry etching techniques. At this time, the support film 30 can be used as an etching stopper. Although there are the bottoms of the holes 13a not covered with the support film 30, as illustrated in FIG. 18, a protection effect is available for the closest lower-layer part 12 of a lower electrode. That is, it is possible to prevent the upper-layer part 14 of a lower electrode provided in the hole 13a from short-circuiting with the most closely adjacent lower-layer part 12 of the lower electrode.

In addition, lower electrodes are mutually supportive of each other through the support film 30. It is therefore possible to prevent the capacitor lower electrodes from collapsing at the time of removing the first sacrificial interlayer insulating film 11 and the second sacrificial interlayer insulating film 13 by wet etching. Consequently, it becomes easy to increase the height of each capacitor lower electrode and thereby increase the electrostatic capacitance of a capacitor.

The above-described structure for supporting the lower-layer part 12 of each capacitor lower electrode by the support film 30 may also be provided for the upper-layer part 14 of each capacitor lower electrode.

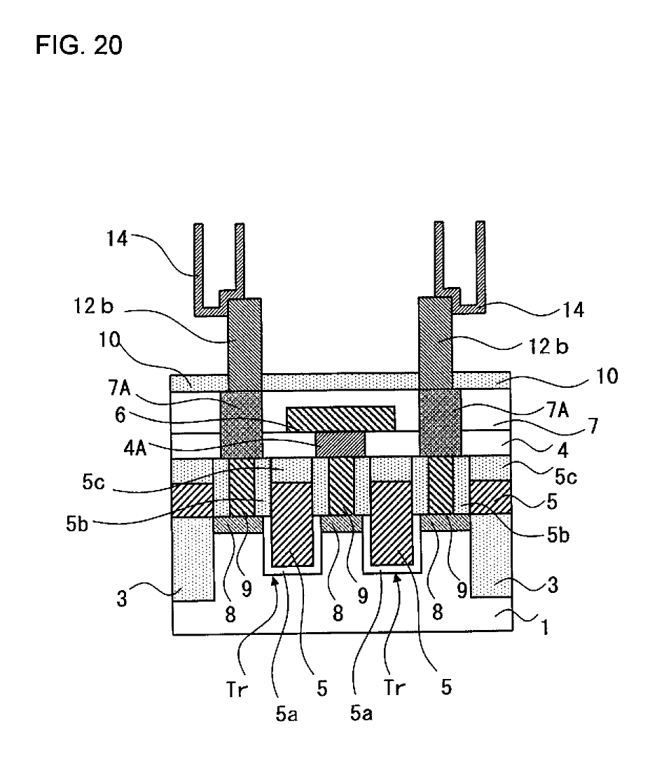

As a third exemplary embodiment, a pillar-type (columnar) lower-layer part 12b of a lower electrode, the hole 11a of which is filled with an electrode material, may be used in place of such a cylindrical lower-layer part of each capacitor lower electrode as described above, as illustrated in FIG. 20. Likewise, the cylindrical upper-layer part of each capacitor lower electrode may also be replaced with a pillar-type upper-layer part.

In addition, the support film described in the second exemplary embodiment may be provided also when a pillar-type electrode is used as described above.

In the exemplary embodiment described heretofore, each capacitor lower electrode has a two-tiered laminated structure including an upper-layer part and a lower-layer part. Alternatively, each capacitor lower electrode may have a three or more-tiered laminated structure. In that case, a second electrode layer to be provided immediately above the lowermost layer of the capacitor lower electrode may be connected with a displacement therefrom. Third and subsequent electrode layers may be successively connected with no displacement from lower electrode layers. In addition, the present invention is also applicable even in cases where some of element-isolating regions for partitioning active regions are formed using another element isolation method in place of STIs where trenches are filled with an insulating film, as long as the active regions are arranged according to a 6 F² layout.

It is apparent that the present invention is not limited to the above embodiments, but may be modified and changed without departing from the scope and spirit of the invention.

What is claimed is:

1. A semiconductor memory device comprising:
a semiconductor substrate;
a plurality of word lines extending in a Y direction on the semiconductor substrate, the word lines being arranged in an X direction perpendicular to the Y direction and being parallel to one another;
a plurality of active regions each elongating and intersecting with two of the word lines, the active regions being arranged in the Y direction and being parallel to one another on the semiconductor substrate;
a capacitance contact plug connected to each end of each of the active regions in the longitudinal direction thereof;
a stack lower electrode including a first lower electrode formed on the capacitance contact plug and a second lower electrode formed on the first lower electrode;
a capacitance insulating film formed on the stack lower electrode; and
an upper electrode formed on the stack lower electrode with an intervention of the capacitance insulating film,
wherein the center position of the second lower electrode is shifted in a predetermined direction from the center position of the first lower electrode.

2. The semiconductor memory device according to claim 1, wherein the arrangement of the first and second lower electrodes with respect to each active region includes one of a first layout in which the center position of the second lower electrode is shifted from the center position of the first lower electrode in such a direction as to come closer to the central part of the active region and a second layout in which the center position of the second lower electrode is shifted from the center position of the first lower electrode in such a direction as to move away from the central part of the active region; and
the first and second layouts are alternately applied with respect to the active regions in the Y direction.

3. The semiconductor memory device according to claim 1, wherein the active regions are arranged such that the longitudinal directions thereof extend along straight lines forming a predetermined angle with the X direction.

4. The semiconductor memory device according to claim 1, wherein the active regions are laid out on the respective straight lines forming the predetermined angle with the X direction.

5. The semiconductor memory device according to claim 4, wherein the first and second layouts are alternately applied with respect to the active regions on the respective straight lines.

6. The semiconductor memory device according to claim 3, wherein the straight lines form an angle of approximately 18° with the X direction.

7. The semiconductor memory device according to claim 1, further comprising a plurality of bit lines intersecting with the word lines, wherein the bit lines are each connected to the central parts of the active regions in the longitudinal directions thereof, with an intervention of respective bit line contact plugs.

8. The semiconductor memory device according to claim 7, wherein the bit lines meander along the X direction such that the bit lines include portions intersecting with the active regions and portions parallel to the longitudinal directions thereof.

9. The semiconductor memory device according to claim 1, wherein the locations of the capacitance contact plugs and the first lower electrodes with respect to the respective active regions are arranged such that the center positions of the first lower electrodes are shifted in such a direction as to come closer to the central parts of the active regions from the center positions of the capacitance contact plugs.

10. The semiconductor memory device according to claim 1, wherein the locations of the capacitance contact plugs and the first lower electrodes with respect to the respective active regions are arranged such that the center positions of the first lower electrodes are shifted along the X direction in such a direction as to come closer to the central parts of the active regions from the center positions of the capacitance contact plugs.

11. The semiconductor memory device according to claim 1, wherein the offset of the center positions of the second lower electrodes is ¾ F along the X direction and ⅓ F along the Y direction.

12. The semiconductor memory device according to claim 1, wherein a distance between the centers of the second lower electrodes adjacent to each other along the X direction is 3 F; and
a distance along the Y direction between the centers of the second lower electrodes adjacent to each other in the Y direction and displaced in the X direction is 2 F.

13. The semiconductor memory device according to claim 1, wherein the plurality of active regions includes first, second and third active regions continuously laid out along the Y direction in the named order, and fourth, fifth and sixth active regions continuously laid out along the Y direction in the named order;
the first active region is adjacent in the longitudinal direction thereof to the fourth active region;
the second active region is adjacent in the longitudinal direction thereof to the fifth active region;
the third active region is adjacent in the longitudinal direction thereof to the sixth active region; and
assuming that the center position of the second lower electrode electrically connected to one end of the first active region in the longitudinal direction thereof is P1, the center position of the second lower electrode electrically connected to one end of the second active region in the longitudinal direction thereof is P2, the center positions of the second lower electrodes electrically connected respectively to one and the other ends of the third active region in the longitudinal direction thereof are P3a and P3b, the center position of the second lower electrode electrically connected to one end of the fourth active region in the longitudinal direction thereof is P4, the center position of the second lower electrode electrically connected to one end of the fifth active region in the longitudinal direction thereof is P5, and the center position of the second lower electrode electrically connected to one end of the sixth active region in the longitudinal direction thereof is P6, there is formed a hexagon having P1, P3a, P3b, P4, P5 and P6 as vertices, P2 being surrounded by the vertices of the hexagon.

14. The semiconductor memory device according to claim 13, wherein a first rhombus having P1, P2, P3a and P3b as vertices is formed;
a second rhombus having P2, P4, P5 and P6 as vertices is formed, the second rhombus being congruent with the first rhombus;
a first parallelogram having P2, P3a, P3b and P6 as vertices is formed; and
a second parallelogram having P1, P2, P4 and P5 as vertices is formed, the second parallelogram being congruent with the first parallelogram.

15. The semiconductor memory device according to claim 1, wherein the first lower electrode and the second lower electrode are cylinder-type electrodes.

16. The semiconductor memory device according to claim 1, wherein the first lower electrode is a pillar-shaped electrode and the second lower electrode is a cylinder-type electrode.

17. A semiconductor memory device comprising:
a memory cell region provided on a semiconductor substrate;
active regions;
word lines intersecting with the active regions, the active regions and the word lines being arranged in the memory cell region according to a 6 F² cell layout; and
a capacitor including a lower electrode, the capacitor being connected to a predetermined position of each of the active regions with an intervention of a capacitance contact plug;
wherein the lower electrode of the capacitor includes a first lower electrode directly connected to the capacitance contact plug and a second lower electrode directly connected to the first lower electrode; and
the center position of the second lower electrode is shifted in a predetermined direction from the center position of the first lower electrode.

18. The semiconductor memory device according to claim 17, wherein the 6 F² cell layout is such that the word lines extending in a Y direction are arranged in an X direction perpendicular to the Y direction and are parallel to one another, and
the center position of the second lower electrode is shifted by an offset of ¾ F along the X direction and by an offset of ⅓ F along the Y direction, with respect to the center position of the first lower electrode.

19. The semiconductor memory device according to claim 18 wherein a distance between the centers of the second lower electrodes adjacent to each other along the X direction is 3 F; and
a distance along the Y direction between the centers of the second lower electrodes adjacent to each other in the Y direction and displaced in the X direction is 2 F.
